(19) United States
(12) Patent Application Publication
(10) Pub. No.: US 2004/0046176 A1
(43) Pub. Date: Mar. 11, 2004

(54) Avalanche phototransistor

(76) Inventors: Gyung-Ock Kim, Seoul (KR); In-Gyoo Kim, Daejeon (KR)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/365,229

(22) Filed: Feb. 12, 2003

(30) Foreign Application Priority Data
Sep. 5, 2002 (KR) 2002-53450

(51) Int. Cl. H01L 27/15

(52) U.S. Cl. 257/83

(57) ABSTRACT

Disclosed is an avalanche phototransistor capable of being used as a photo detector of high performance. The avalanche phototransistor comprises an emitter photoabsorption layer having a function to detect an infrared light, a thin avalanche-gain layered-structure including a charge layer and a multiplication layer having a thickness of 5,000 Å or less, and a hot electron transition layer. The avalanche phototransistor employs a three-terminal structure which consists of an emitter, a base and a collector. Even if a lower voltage than that of an avalanche photodiode is applied to the avalanche phototransistor, high gain can be obtained and sensitivity of the phototransistor can be increased. High current, high output and high operation speed can be accomplished using a hot electron effect. Further, stability of elements and reliance can be increased, and multiple operation functions can be obtained due to the increased number of terminals.

This application claims the priority of Korean Patent Application No. 2002-53450, filed Sep. 5, 2002, in the Korean Intellectual Property Office, the disclosure of which is incorporated herein in its entirety by reference.

### BACKGROUND OF THE INVENTION

1. Field of the Invention

The present invention relates to an avalanche photo detector, and more particularly, to an avalanche photo detector having low operation voltage, high operation speed and high sensitivity by applying a three-terminal structure to the photo detector and including a hot electron transition layer.

2. Description of the Related Art

As demands for optical communication systems of super high speed and mass capacity and image processing systems have been recently increased, researches on photo detectors essentially used in these systems have been actively pursued. Most of such researches relate to methods for achieving high speed and high sensitivity for the photo detectors.

While most of the conventional photo detectors are of a PIN type having simple structure, a photo detector of various hetero-junction structures has been completed based on developments in semiconductor technologies such as molecular beam epitaxy and metal organic chemical vapor deposition. Thus, the PIN type photo detector of simple structure has been replaced with an avalanche photo detector (to be referred to hereinafter as an APD). Since the APD employs avalanche gain, the APD has an advantage in that sensitivity is higher than that of the PIN type photo detector.

So far, an avalanche photodiode has been used as APD. However, the avalanche photodiode has drawbacks in that a very high operation voltage is required for obtaining the avalanche gain and operation speed is low. Further, the avalanche photodiode has drawbacks in that an electric preamplifier is inevitably required because of low output current.

### SUMMARY OF THE INVENTION

To solve the above and other problems, it is an aspect of the present invention to provide an improved avalanche photo detector which has features such as high gain, high sensitivity, high-saturation current, high output and high operation speed, even if a relative low operation voltage is applied.

Further, the present invention proposes an avalanche phototransistor as a new and high performance avalanche photo detector.

According to the above and other aspects of the invention, an avalanche phototransistor comprises a collector layer, a base layer and emitter layer which are sequentially laminated on a semiconductor substrate, an emitter photoabsorption layer which is formed between the emitter layer and the base layer, a thin avalanche-gain layered-structure which is formed between the photoabsorption layer and the base layer, and is comprised of a charge layer and a multiplication layer having a thickness of 5,000 Å or less, a hot electron transition layer which is formed between the base layer and the collector layer, and a collector electrode, a base electrode and an emitter electrode which respectively apply potential to the collector layer, the base layer and the emitter layer.

The photoabsorption layer is comprised of a bulk-type single material layer, a thin film layer having a thickness of 1000 Å or less, a self-assembled quantum dot layered-structure, a quantum well structure, a vertical type quantum dot array structure manufactured using a double-barrier quantum well structure or a multiple-barrier quantum well structure, or a quantum wire array structure. A spacer layer for distribution and control of impurities may be formed on the avalanche-gain layered-structure, if necessary.

The hot electron transition layer is composed of a semiconductor material having a bandgap wider than the base layer and the collector layer. Thus, the hot electron transition layer moves electrons at high speed, and may be a multilayer film comprised of a p-type semiconductor, an n-type semiconductor and an intrinsic semiconductor.

In the avalanche phototransistor according to the above and other aspects of the invention, electrons created in the photoabsorption layer by absorbing a light signal (infrared signal) are interband-transited or intersubband-transited. When an external voltage is applied, the created electrons are multiplicated by passing through the charge layer and the multiplication layer, and the multiplicated electrons move at high speed passing through the hot electron transition layer formed between the base layer and the collector layer. Thus, even if a relative low operation voltage is applied, high gain can be obtained. Further, high speed and low noise of the avalanche photo detector can be obtained by the thin multiplication layer.

Accordingly, since the avalanche phototransistor according to the present invention includes the avalanche-gain layered-structure, the hot electron transition layer and a three-terminal structure, high gain can be achieved. High sensitivity, low operation voltage, high output and high operation speed can be achieved due to the high gain. Stability can be ensured by suppressed breakdown of the photo detector. Further, since the low operation voltage is used, the avalanche phototransistor according to the present invention has many advantages. Since high gain is achieved, low photo-absorptivity can be compensated. Multiple operation functions can be obtained using the three-terminal structure. The infrared signal of various wavelengths can be detected, because the high degree of selection of the photoabsorption layer.

### BRIEF DESCRIPTION OF THE DRAWINGS

The above and other aspects and advantages of the present invention will become more apparent by describing in detail preferred embodiments thereof with reference to the attached drawings in which:

FIG. 1 is a cross sectional view of an avalanche phototransistor according to a first embodiment of the present invention;

FIG. 2 is a cross sectional view of an avalanche phototransistor according to a second embodiment of the present invention;

FIG. 3 is a cross sectional view of a waveguide type avalanche phototransistor according to a third embodiment of the present invention;

FIG. 4 is a cross sectional view of a waveguide-fed type avalanche phototransistor according to a fourth embodiment of the present invention;

FIGS. 5A to 10B are diagrams illustrating various structures of a photoabsorption layer which can be applied to an avalanche phototransistor according to the present invention;

FIGS. 11A and 11B are respective schematic energy band diagrams under an equilibrium state not applying a voltage and a voltage applying state in an avalanche phototransistor according to the present invention; and

FIGS. 12A and 12B are respective schematic energy band diagrams under an equilibrium state not applying a voltage and a voltage applying state in an avalanche phototransistor according to the present invention, in a case of introducing a photoabsorption layer having a quantum structure.

### DETAILED DESCRIPTION OF THE INVENTION

The present invention now will be described more fully with reference to the accompanying drawings, in which preferred embodiments of the invention are shown. This invention may, however, be embodied in many different forms and should not be construed as being limited to the embodiments set forth herein; rather, these embodiments are provided so that this disclosure will be thorough and complete, and will fully convey the concept of the invention to those skilled in the art.

<First Embodiment>

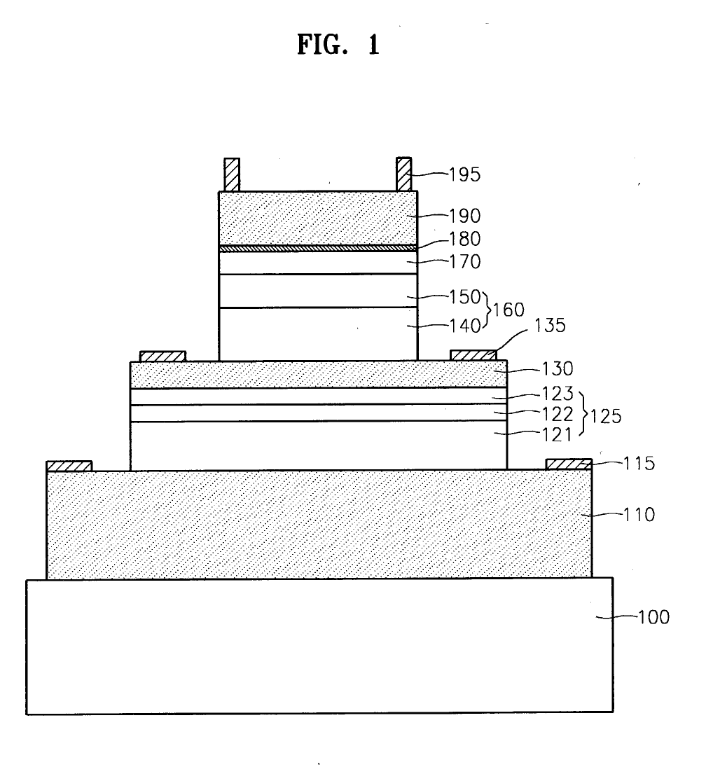

FIG. 1 is a cross sectional view of an avalanche phototransistor according to a first embodiment of the present invention. The avalanche phototransistor shown in FIG. 1 has features such as high gain, high output, high operation speed and a three-terminal structure.

Referring to FIG. 1, the avalanche phototransistor is configured such that a collector layer 110, a base layer 130 and an emitter layer 190 are sequentially laminated on a semiconductor substrate 100. The avalanche phototransistor has a three-terminal structure in which a collector electrode 115, a base electrode 135 and an emitter electrode 195 apply a potential to the collector layer 110, the base layer 130 and the emitter layer 190, respectively. The emitter electrode 195 is formed in the form of a ring on the emitter layer 190 so that the emitter electrode 195 defines a light-receiving part and is configured to receive an external predetermined voltage.

An emitter photoabsorption layer 170 is formed between the emitter layer 190 and the base layer 130. The photoabsorption layer 170 absorbs a light signal so that electrons are created in the photoabsorption layer 170. Further, a thin avalanche-gain layered-structure 160 is formed between the photoabsorption layer 170 and the base layer 130 so that the created electrons are multiplicated through the avalanche-gain layered-structure 160. The avalanche-gain layered-structure 160 is comprised of a charge layer 150 and a thin multiplication layer 140 having a thickness of 5,000 Å or less. The multiplication layer 140 is composed of a bulk-type single material layer or a super lattice structure.

When a light signal having an energy higher than a bandgap energy is irradiated to the photoabsorption layer 170, electrons are created in the photoabsorption layer 170 and transited to the conduction band leaving behind holes in the valance band. The photoabsorption layer 170 can be formed in various structures. For example, the photoabsorption layer 170 may be comprised of a bulk-type single material layer, a thin film layer having a thickness of 1000 Å or less, a self-assembled quantum dot layered-structure, a quantum well-structure, a vertical type quantum dot array structure manufactured by using a double-barrier quantum well structure or a multiple-barrier quantum well structure, or a quantum wire array structure. A spacer layer 180 functioning as a buffer layer may be optionally formed between the photoabsorption layer 170 and the emitter layer 190.

A hot electron transition layer 125 is formed between the base layer 130 and the collector layer 110. The hot electron transition layer 125 makes the electrons transited from the base layer 130 to move at a high-speed, and then the electrons are reached to the collector layer 110. The hot electron transition layer 125 is made of a material having a bandgap wider than the base layer 130 and the collector layer 110, and may be comprised of multilayer films 121, 122 and 123 as shown in FIG. 1.

In the structure of such avalanche phototransistor, the excited electrons in the photoabsorption layer 170 are multiplicated passing through the thin avalanche-gain layered-structure 160, move at high-speed passing through the hot electron transition layer 125, and reach the collector layer 110. Thus, even if a lower voltage is applied to the avalanche transistor compared with the prior art, features such as high sensitivity, high gain, high output and high speed can be obtained.

In the phototransistor of the present invention, the collector layer 110, the base layer 130 and the emitter layer 190 may be configured in either a pnp type or an npn type. Since factors such as material and doping concentrations for impurities of the collector layer, the base layer and the emitter layer and other elements for configuring the phototransistor considerably affect features such as the gain and speed of the APD, these factors must be carefully determined. For example, the emitter layer 190 may be composed of a p+-InAlAs layer, and the spacer layer 180 may be composed of an i-InAlAs layer. The photoabsorption layer 170 may be composed of an i-InGaAs single material having a thickness of 1,000 Å or less, and the avalanche-gain layered-structure 160 may be composed of a p-InAlAs charge layer 150 and a thin i-InAlAs multiplication layer 140 having a thickness of 5,000 Å or less. The base layer 130 may be composed of an n-InAlAs layer or a p-InAlAs layer having a thickness of 2,000-3,000 Å or less. The hot electron transition layer 125 may be a multilayer film composed of a p-InAlAs layer 123, an n-InAlAs layer 122 having a thickness of 500 Å or less, and an i-InAlAs layer 121 having a thickness of about 2,000 Å. The collector layer 110 may be composed of an n-InAlAs layer, and n-InP may be used as the substrate 100.

The present invention is not limited to the embodiments set forth herein and the present invention can be embodied while changing the kind of semiconductor material and the doping concentration for impurities, and so on; rather, the embodiment are provided so that this disclosure will be thorough and complete, and will fully convey the concept of the invention to those skilled in the art. Although the present invention has been described only the case where the electrons are majority carrier, it must be noted that the present invention can be applied to the case where the holes are majority carrier.

<Second Embodiment>

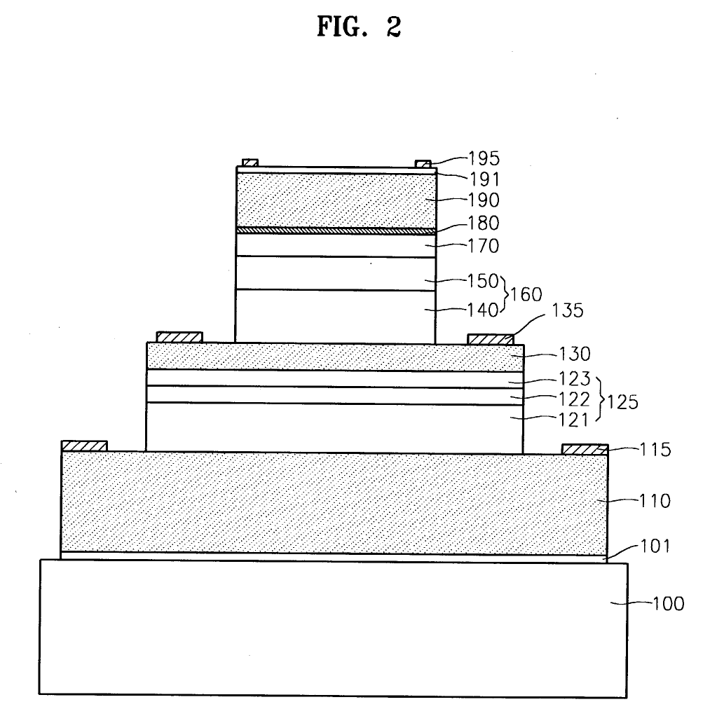

An avalanche phototransistor according to the present invention can be embodied as a resonant-cavity type avalanche phototransistor. FIG. 2 is a cross sectional view of such resonant-cavity type avalanche phototransistor. In FIG. 2, the same reference numerals as those in FIG. 1 represent the same element, and thus their description will be omitted.

Referring to FIG. 2, the resonant-cavity type avalanche phototransistor is characterized in that a lower mirror 101 comprised of a quarter-wave stack is interposed between the collector layer 110 and the substrate 100, and an upper mirror 191 using dielectric multilayer is laminated on the emitter layer 190. The lower mirror 101 has a lattice-matching structure on the substrate 100, and may be comprised of a semiconductor DBR (Distributed Bragg Reflector) in which semiconductor layers having different refractive indexes are alternatively formed with several periods.

By applying the resonant-cavity type avalanche phototransistor using the mirror structure as described above, quantum efficiency can be increased, functions of elements can be improved, and high speed can be achieved. Accordingly, the phototransistor shown in FIG. 2 can be employed as a super high speed infrared signal detecting element.

<Third Embodiment>

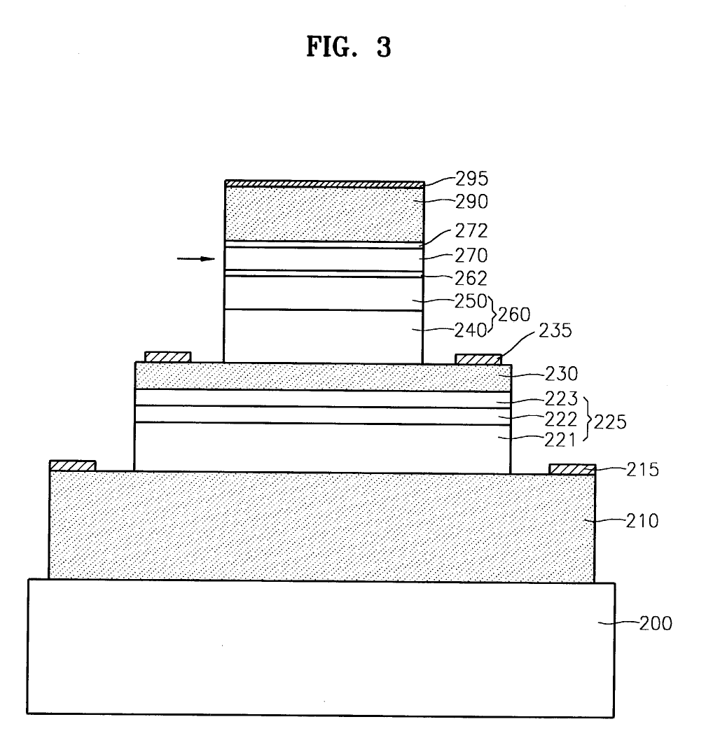

An avalanche phototransistor according to the present invention can be embodied as a waveguide type avalanche phototransistor. FIG. 3 is a cross sectional view of such waveguide type avalanche phototransistor.

The waveguide type avalanche phototransistor shown in FIG. 3 is characterized in that first and second guiding layers 272 and 262 are respectively formed on an upper portion and a lower portion of a photoabsorption layer 270. The waveguide type avalanche phototransistor includes an emitter layer 290 composed of a p+-InAlAs layer, the first guiding layer 272 composed of an i-InAlAs layer, the photoabsorption layer 270 composed of an i-InGaAs thin film layer, the second guiding layer 262 composed of an i-InAlAs layer, an avalanche-gain layered-structure 260 composed of a p-InAlAs charge layer 250 and a thin i-InAlAs multiplication layer 240 having a thickness of 2,000 Å or less, a thin base layer 230 having a thickness of 2,000 Å or less, a hot electron transition layer 225 composed of a p-InAlAs layer 223, an n-InAlAs layer 222 having a thickness of 500 Å or less, and an i-InAlAs layer 221 having a thickness of about 2,000 Å, and a collector layer 210 composed of an n-InAlAs layer. The above layers are formed on a semiconductor substrate 200 such as an n-InP type substrate. The waveguide type avalanche phototransistor has a three-terminal structure in which a collector electrode 215, a base electrode 235, and an emitter electrode 295 apply potential to the collector layer 210, the base layer 230 and the emitter layer 290, respectively.

The emitter electrode 295 is formed on the emitter layer 290 in the form of sheet, and a light signal is incident on the photoabsorption layer 270 as indicated by the arrow of FIG. 3. Features which are not particularly described in the present embodiment are the same as in the first embodiment, and thus their description will be omitted.

<Fourth Embodiment>

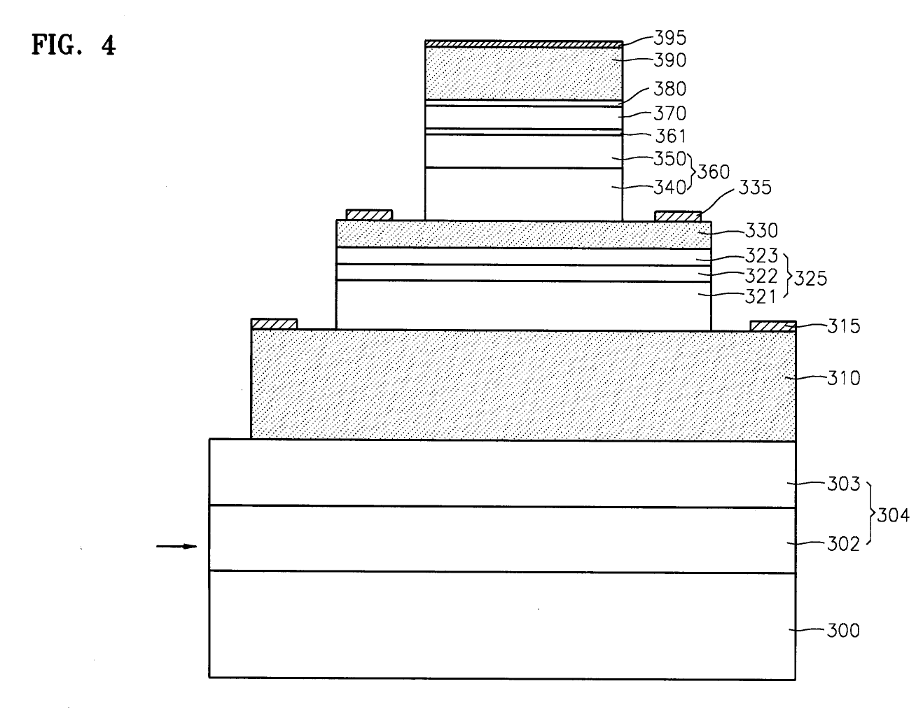

An avalanche phototransistor according to the present invention can be embodied as a waveguide-fed type avalanche phototransistor. FIG. 4 is a cross sectional view of such waveguide-fed type avalanche phototransistor.

The waveguide-fed type avalanche phototransistor is characterized in that a waveguide layered-structure 304 is interposed between a collector layer 310 and a substrate 300.

Specifically, the waveguide type avalanche phototransistor includes an emitter layer 390 composed of a p+-InAlAs layer, a spacer layer 380 composed of an i-InAlAs layer, a photoabsorption layer 370 composed of an i-InGaAs thin film layer, a graded spacer layer 361 composed of an i-InGaAlAs layer (i-InGa_{0.47(1-x)}Al_{0.47x}As, here x is in range from 0 to 1), an avalanche-gain layered-structure 360 composed of a p-InAlAs charge layer 350 and an i-InAlAs multiplication layer 340 having a thickness of 2,000 Å or less, a base layer 330 having a thickness of 2,000 Å or less, a hot electron transition layer 325 composed of a p-InAlAs layer 323, an n-InAlAs layer 322 having a thickness of 500 Å or less, and an i-InAlAs layer 321 having a thickness of about 2,000 Å, a collector layer 310 composed of an n-InAlAs layer, and the waveguide layered-structure 304 composed of a guiding layer 303 composed of an InGaAlAs layer and an InAlAs layer 302. The above layers are formed on a semiconductor substrate 300 such as an n-InP type substrate. The waveguide-fed type avalanche phototransistor has a three-terminal structure in which a collector electrode 315, a base electrode 335 and an emitter electrode 395 apply a potential to the collector layer 310, the base layer 330 and the emitter layer 390, respectively. The emitter electrode 395 is formed on the emitter layer 390 in the form of sheet, and a light signal is incident on the waveguide layered-structure 304 as indicated by the arrow of FIG. 4. Features which are not particularly described in the present embodiment are the same as in the first embodiment, and thus their description will be omitted.

As described in the above first to fourth embodiments, since the avalanche phototransistor of the present invention as APD further includes the base layer and the hot electron transition layer compared with the conventional avalanche photodiode, the very thin avalanche-gain layered-structure can be applied so that high gain, high speed, high-saturated current and high output can be obtained compared with the conventional avalanche photodiode. Further, since the avalanche phototransistor of the present invention employs the three-terminal structure, multiple operation functions can be obtained.

<Examples of Photoabsorption Layer>

Next, various structures of a photoabsorption layer used in the avalanche phototransistor according to the present invention will be described. As described below, many various structures can be applied to the photoabsorption layer of the present invention. The infrared signal of various wavelengths can be detected, due to the high degree of selection assured by the photoabsorption layer via the various structures of the photoabsorption layer.

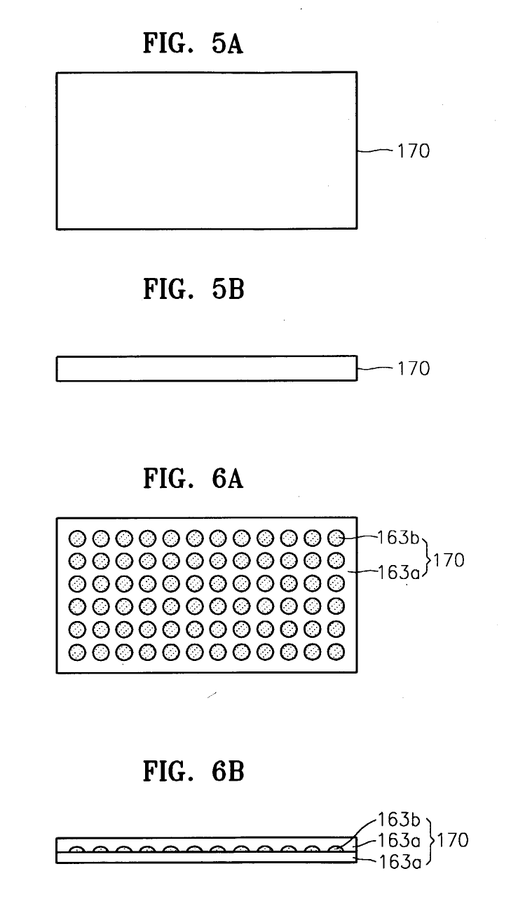

FIGS. 5A through 10B are structural horizontal cross sectional views and structural transverse cross sectional views of a photoabsorption layer capable of being used as the photoabsorption layers 170, 270 and 370 of FIGS. 1 through 4. FIGS. 5A, 6A, 7A, 8A, 9A and 10A are horizontal cross sectional views of the photoabsorption layer to the substrate, and FIGS. 5B, 6B, 7B, 8B, 9B and 10B are transverse cross sectional views of the photoabsorption layer to the substrate. Although only the photoabsorption layer 170 shown in FIGS. 1 and 2 is shown in FIGS. 5A through 10B for the sake of convenience, it is obvious to those skilled in the art that a layer as the photoabsorption layer 170 of FIGS. 1 and 2 can be applied to the photoabsorption layer 270 of FIG. 3 and the photoabsorption layer 370 of FIG. 4.

FIGS. 5A and 5B show the photoabsorption layer 170 composed of a bulk-type single material layer or a thin film layer having a thickness of 1,000 Å or less. The photoabsorption layer composed of an i-InGaAs thin film layer was introduced in the above first through fourth embodiments.

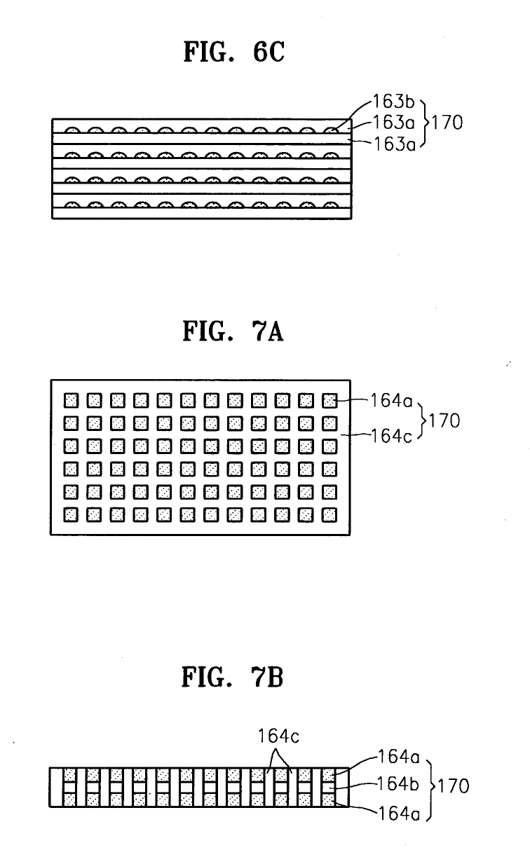

FIGS. 6A and 6C show the photoabsorption layer 170 comprised of a self-assembled quantum dot array layered-structure. As shown in FIG. 6C, the photoabsorption layer 170 can be comprised of the self-assembled quantum dot array layered-structure stacked several times. As well known, the self-assembled quantum dot is completed by laminating a material 163b having a large lattice constant, on a material 163a having a small lattice constant so that the material 163b is strained, agglomerating the material 163b, and laminating the material 163a on the material 163b. Generally, since a material of small lattice constant has a bandgap wider than a material of large lattice constant, the agglomerated material 163b surrounded by the materials 163a forms a narrow bandgap interposed between wide bandgaps, whereby the material 163b becomes quantum dots. Here, the reference numeral 163a may be, for example, a GaAs layer, and the reference numeral 163b may be, for example, an InAs quantum dot.

FIGS. 7A and 7B show the photoabsorption layer 170 comprised of a quantum dot array layered-structure through lateral confinement of a double barrier quantum well structure. A reference numeral 164a represents a quantum barrier layer composed of an i-InAlAs layer, a reference numeral 164b represents a quantum dot using an InGaAs quantum well layer having a thickness of 100 Å or less, and a reference numeral 164c represents an insulating layer such as SiN. As well known, the quantum barrier layer is referred to as a material layer having a wider bandgap than the quantum well layer.

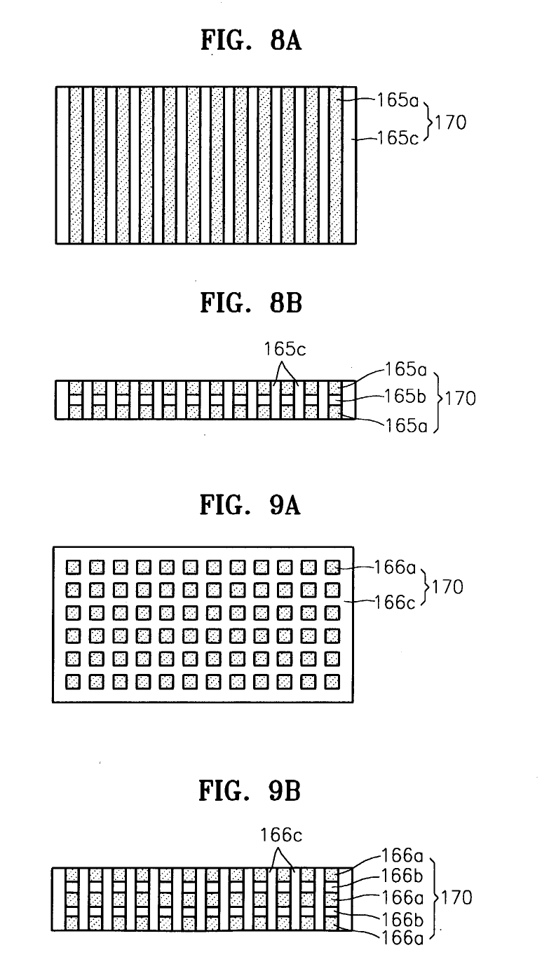

FIGS. 8A and 8B show the photoabsorption layer 170 comprised of a quantum wire array layered-structure through lateral confinement in a double barrier quantum well type epitaxy structure. A reference numeral 165a represents a quantum barrier layer composed of an i-InAlAs layer, a reference numeral 165b represents a quantum wire using an InGaAs quantum well layer having a thickness of 100 Å or less, and a reference numeral 165c represents an insulating layer.

FIGS. 9A and 9B show the photoabsorption layer 170 comprised of a vertical quantum dot array layered-structure through lateral confinement in a triple barrier quantum well type epitaxy structure. A reference numeral 166a represents an i-AlAs layer, a reference numeral 166b represents a quantum dot using a GaAs quantum well layer having a thickness of 100 Å or less, and a reference numeral 166c represents an insulating layer. A method of forming a structure of the photoabsorption layer 170 of FIGS. 9A and 9B is similar to the method of FIGS. 7A and 7B.

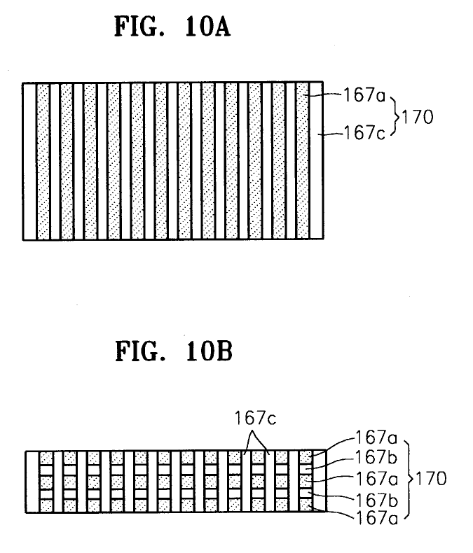

FIGS. 10A and 10B show the photoabsorption layer 170 comprised of a vertical quantum wire array layered-structure using a triple wall quantum well structure. A method of forming the structure of the photoabsorption layer 170 of FIGS. 10A and 10B is similar to the method of FIGS. 8A and 8B. A reference numeral 167a represents a quantum barrier layer composed of an i-InAlAs layer, a reference numeral 167b represents a quantum wire using an InGaAs quantum well layer having a thickness of 100 Å or less, and a reference numeral 167c represents an insulating layer.

(Energy Band Diagram)

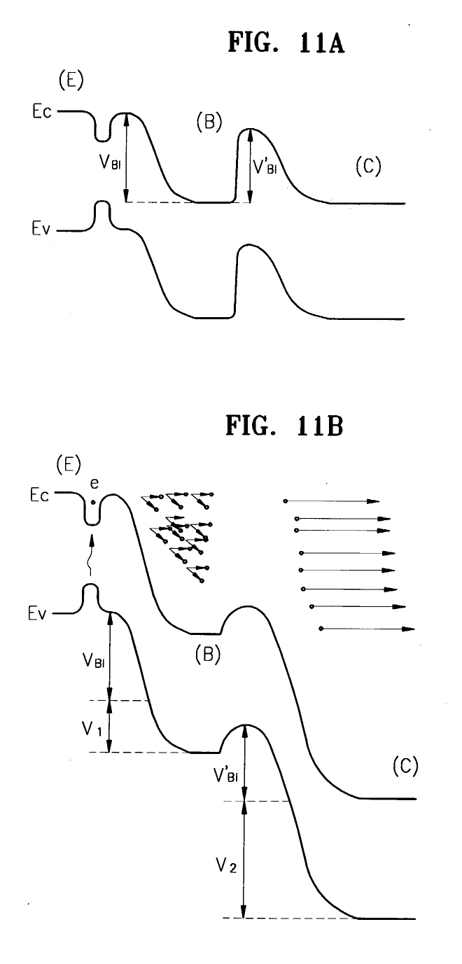

FIGS. 11A and 11B are schematic energy band diagrams illustrating an energy state of the avalanche phototransistor according to the present invention. Particularly, FIGS. 11A and 11B are schematic energy band diagrams in a case of not using the quantum structure as the photoabsorption layer of FIGS. 1 to 4. In the drawings, reference elements (E), (B) and (C) represent an emitter layer, a base layer and a collector layer, respectively. Further, reference elements Ec and Ev represent the conduction band and the valance band, respectively.

FIG. 11A shows an energy band of the avalanche phototransistor under a thermal equilibrium state when being not applied a voltage from external. In FIG. 11A, a reference element V_{BI} represents a built-in potentional between the photoabsorption layer and the avalanche-gain layered-structure, and a reference element V′_{BI} represents a built-in potentional between the base layer and the collector layer.

FIG. 11B shows an energy band of the avalanche phototransistor when a voltage is applied from external. Electrons in the photoabsorption layer absorb an infrared light, and then the electrons are interband-transited into the conduction band. The transited electrons are multiplicated by voltages V₁ and V₂ applied from the exterior and built-in potentionals V_{BI} and V′_{BI} in the phototransistor while passing through the charge layer and the multiplication layer. Strength of electric field of the avalanche-gain layered-structure is controlled by a voltage, which is applied to both sides of the avalanche-gain layered-structure. V₁ is a voltage applied between the emitter layer and the base layer, and V₂ is a voltage applied between the base layer and the collector layer. The voltages V₁ and V₂ have reverse polarities to each other. In a case of a multiplication structure using electrons, the voltage V₁ is a negatively biased voltage, and the voltage V₂ is a positively biased voltage. The multiplicated electrons move at high speed while passing through the hot electron transition layer to reach to the collector layer, thereby producing a large electric signal (output).

The reason the electrons created in the photoabsorption layer are multiplicated by passing through the charge layer and the multiplication layer is that impact ionization occurs in the multiplication layer due to a very high electric field effect generated by applying the exterior reverse voltage. That is, since the energy level of the avalanche-gain layered-structure including the charge layer and the multiplication layer is lower than that of the emitter layer by the amount of the voltage V₁ so that a potential difference between the avalanche-gain layered-structure and the emitter layer is large and the strength of the electric field of the avalanche-gain layered-structure is high, the avalanche-gain by the impact ionization effect can be obtained. Further, the reason the moving speed of the multiplicated electrons is high by passing through the hot electron transition layer is that the energy level of the hot electron transition layer is lower than that of the avalanche-gain layered-structure by the amount of the V₂ so that the multiplicated electrons can be hot-electrons.

Accordingly, although the light signal of a very low intensity is applied to the avalanche phototransistor, since the potential difference between the layers occurs as described above, the avalanche phototransistor according to the present invention can sensitively detect the light signal.

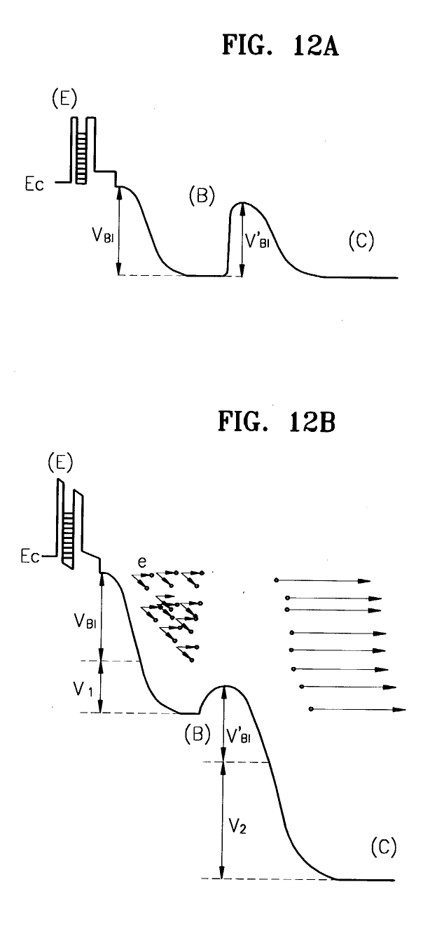

FIGS. 12A and 12B are schematic energy band diagrams of the avalanche phototransistor according to the present invention in a case of applying a quantum structure to the photoabsorption layer of FIGS. 1 through 4. The quantum structure in FIGS. 12A and 12B is referred to as a quantum well structure, a quantum dot structure or a quantum wire array structure. Similar to FIGS. 11A and 11B, in FIGS. 12A and 12B, reference elements (E), (B) and (C) represent an emitter layer, a base layer and a collector layer, respectively. Further, a reference element Ec represents the conduction band.

FIG. 12A shows an energy band of the avalanche phototransistor under a thermal equilibrium state when an external voltage is not applied. In FIG. 12A, a reference element V_{BI} represents a built-in potential between the photoabsorption layer of the quantum structure and the avalanche-gain layered-structure, and a reference element V′_{BI} represents a built-in potential between the base layer and the collector layer. Since the photoabsorption layer of the quantum structure is used in the avalanche phototransistor, the energy band of the photoabsorption layer is split into a number of sub-bands as shown in FIG. 12A.

FIG. 12B shows an energy band of the avalanche phototransistor when an external voltage is applied. Electrons in the photoabsorption layer absorb an infrared light, and the electrons are intersubband-transited into a band of sharp excitation level. The transited electrons, as described in FIG. 11B, are multiplicated by applying the external voltages V₁ and V₂ and the built-in potentials V_{BI} and V′_{BI} while passing through the charge layer and the multiplication layer. The multiplicated electrons passes through the hot electron transition layer to reach to the collector layer. An infrared absorbing wavelength is determined by confinement energy level of quantum dot, quantum well or quantum wire

As described so far, since the avalanche phototransistor according to the present invention includes the avalanche-gain layered-structure, the hot electron transition layer, and a three-terminal structure, high gain can be achieved. Therefore, high sensitivity, low operation voltage, high output and high operation speed can be achieved. Stability can be ensured by suppressed breakdown of the photo detector. Further, since the low operation voltage is used, the avalanche phototransistor according to the present invention has many advantages. Since high gain is achieved, low photo-absorptivity can be compensated, and multiple operation functions can be obtained using the three-terminal structure. The infrared signal of various wavelengths can be selected and processed, because the high degree of selection of the photoabsorption layer.

The avalanche phototransistor of the present invention can be used for long-distance communication and in a case where a very high sensitivity is required, for example, for signal photon counting. Since the avalanche phototransistor of the present invention does not require an electric preamplifier, which is inevitably required in the avalanche photodiode, by accomplishing high gain, the avalanche phototransistor can be applied to a photo detector of high speed and high output, a high speed infrared signal detector, a high speed infrared signal amplifier or a light receiver. Further, the avalanche phototransistor can be applied to an ultra high speed switching device, a digital logic device or a high speed infrared digital logic device having multiple functions due to the increased degree of the freedom assured by the multi-terminal operation, for example, three or more terminals.

While the present invention has been particularly shown and described with reference to preferred embodiments thereof, it will be understood by those of ordinary skill in the art that various changes in form and details may be made therein without departing from the spirit and scope of the present invention as defined by the appended claims.

What is claimed is:

1. An avalanche phototransistor comprising:
a collector layer, a base layer and an emitter layer which are sequentially laminated on a semiconductor substrate;
an emitter photoabsorption layer which is formed between the emitter layer and the base layer;
a thin avalanche-gain layered-structure which is formed between the photoabsorption layer and the base layer, and including a charge layer and a multiplication layer having a thickness of 5,000 Å or less;
a hot electron transition layer which is formed between the base layer and the collector layer; and
a collector electrode, a base electrode and an emitter electrode which respectively apply a potential to the collector layer, the base layer and the emitter layer.

2. The avalanche phototransistor of claim 1, wherein the photoabsorption layer includes a bulk-type single material layer, a thin film layer having a thickness of 1000 Å or less, a self-assembled quantum dot layered-structure, a quantum well structure, a vertical type quantum dot array structure manufactured using a double-barrier quantum well structure or a multiple-barrier quantum well structure, or a quantum wire array structure.

3. The avalanche phototransistor of claim 1, wherein the multiplication layer is a bulk-type single material layer or a super lattice structure.

4. The avalanche phototransistor of claim 1, wherein guiding layers are formed an upper portion and a lower portion of the photoabsorption layer, respectively, so that the avalanche phototransistor is manufactured in a waveguide type structure.

5. The avalanche phototransistor of claim 1, wherein a waveguide layered-structure is introduced between the collector layer and the substrate so that the avalanche phototransistor is manufactured in a waveguide-fed type structure.

6. The avalanche phototransistor of claim 1, wherein a lower mirror includes a quarter-wave stack is interposed between the collector layer and the substrate, and an upper mirror using dielectric multilayer is laminated on the emitter layer so that the avalanche phototransistor is manufactured in a resonant-cavity type structure.

7. The avalanche phototransistor of claim 1, further comprising a spacer layer on the avalanche-gain layered-structure.

8. The avalanche phototransistor of claim 5, further comprising a spacer layer on the avalanche-gain layered-structure.

9. The avalanche phototransistor of claim 6, further comprising a spacer layer on the avalanche-gain layered-structure.

10. The avalanche phototransistor of claim 1, further comprising a graded spacer layer on the avalanche-gain layered-structure.

11. The avalanche phototransistor of claim 4, further comprising a graded spacer layer on the avalanche-gain layered-structure.

12. The avalanche phototransistor of claim 5, further comprising a graded spacer layer on the avalanche-gain layered-structure.

13. The avalanche phototransistor of claim 6, further comprising a graded spacer layer on the avalanche-gain layered-structure.

14. The avalanche phototransistor of claim 1, wherein the hot electron transition layer includes a semiconductor material having a bandgap wider than that of the base layer and the collector layer.

15. The avalanche phototransistor of claim 1, wherein the hot electron transition layer is a multilayer film including a p-type semiconductor, an n-type semiconductor and an intrinsic semiconductor.
